(19) United States
(12) Patent Application Publication
(10) Pub. No.: US 2014/0046609 A1
(43) Pub. Date: Feb. 13, 2014

(54) METERING CHIP AND METHOD OF METERING

(71) Applicant: Samsung Electro-Mechanics Co., Ltd., Gyeonggi-do (KR)

(72) Inventors: Wan Cheol Yang, Gyeonggi-do (KR); Kyung Uk Kim, Gyeonggi-do (KR)

(73) Assignee: SAMSUNG ELECTRO-MECHANICS CO., LTD., Gyeonggi-do (KR)

(21) Appl. No.: 13/951,405

(22) Filed: Jul. 25, 2013

(30) Foreign Application Priority Data
Aug. 13, 2012 (KR) 10-2012-0088353

(51) Int. Cl. G01R 21/133

(52) U.S. Cl. CPC G01R 21/133
USPC 702/60

(57) ABSTRACT

Provided is a metering chip and a method of metering. The metering chip includes a first analog-to-digital converter connected to an output terminal of a current sensor for detecting a power supply current; and a noise canceller connected to an output terminal of the first analog-to-digital converter and can reduce its power consumption and size while accurately detecting a low current than before.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2012-0088353, entitled filed Aug. 13, 2012, which is hereby incorporated by reference in its entirety into this application.”

### BACKGROUND OF THE INVENTION

1. Field of the Invention

The present invention relates to a metering chip and a method of metering.

2. Description of the Related Art

A metering chip is used for measuring power used in various electronic devices. In the past, a mechanical watt-hour meter was mainly widely used but has been displaced by an electronic watt-hour meter recently.

The electronic watt-hour meter is disclosed in many documents such as Patent Document 1.

Meanwhile, in recent times, there is continuing research on intelligent appliances related to smart grid.

Here, the intelligent appliances mean home appliances that have a demand-response (DR) interlocking function to monitor and display power usage or operate except a time of high demand for power, and there are continuous efforts to give the DR interlocking function to the home appliances such as refrigerators or air conditioners with relatively high power consumption.

When the DR interlocking function is well utilized, since carbon dioxide emissions can be reduced macroscopically as well as electricity charges, eco-friendly home appliances can be implemented.

The metering chip, which is an essential component required for implementing the above intelligent home appliances, is mounted on the home appliances and monitors power consumption of the home appliances in real time to provide the results of monitoring to controllers of the home appliances, thus implementing the DR interlocking function.

Since the metering chip mounted on the intelligent home appliances is not used for accurate charging unlike a typical watt-hour meter, it is enough if the metering chip satisfies only relatively low accuracy compared to a watt-hour meter for charging. However, since the metering chip should be mounted on the home appliances, the smaller the metering chip and the lower its power consumption, the higher competitiveness.

Accordingly, an analog-to-digital converter with a resolution of a small bit number should be used instead of a high accuracy analog-to-digital converter used in the typical watt-hour meter to reduce power consumption. When reducing the resolution of the analog-to-digital converter like this, a signal to noise ratio (SNR) is also reduced, thus causing a significant degradation of performance of measuring power by detecting a low current.

### RELATED ART DOCUMENTS

### Patent Documents

Patent Document 1: Korean Patent Laid-open Publication No. 2010-0032534

### SUMMARY OF THE INVENTION

The present invention has been invented in order to overcome the above-described problems and it is, therefore, an object of the present invention to provide a metering chip that can reduce its power consumption and size while accurately detecting a low current than before, and a method of metering.

In accordance with one aspect of the present invention to achieve the object, there is provided a metering chip for calculating the amount of power by detecting a power supply current and a power supply voltage, including: a first analog-to-digital converter connected to an output terminal of a current sensor for detecting the power supply current; and a noise canceller connected to an output terminal of the first analog-to-digital converter.

At this time, the noise canceller may include a digital filter connected to the output terminal of the first analog-to-digital converter; and an adder connected to the output terminal of the first analog-to-digital converter and an output terminal of the digital filter.

Further, the digital filter may be a filter which passes only a signal deviated from a center frequency domain of a signal output from the first analog-to-digital converter, and the adder may subtract the signal passing through the digital filter from the signal output from the first analog-to-digital converter to output the subtracted signal.

Further, a transfer function H(z) of the digital filter is

$$H ( z ) = \frac{1 - 2 cos {ω}_{0} {z}^{- 1} + {z}^{- 2}}{1 - 2 r cos {ω}_{0} {z}^{- 1} + {r}^{2} {z}^{- 2}} .$$

At this time, r is

$$r = 1 - \frac{Δ f}{{f}_{s}} π$$

as a radius from a center point to a pole position on a unit circle of a z plane. At this time, fₒ is a center frequency, Δf is a band frequency, fₛ is a sampling frequency, and ωₒ is

$${ω}_{0} = \frac{2 π {f}_{0}}{{f}_{s}}$$

as an angular frequency of a pole on the unit circle of the z plane, and the adder may subtract the signal passing through the digital filter from the signal output from the first analog-to-digital filter to output the subtracted signal.

In accordance with another aspect of the present invention to achieve the object, there is provided a metering chip including: a first analog-to-digital converter connected to an output terminal of a current sensor for detecting a power supply current; a second analog-to-digital converter connected to an output terminal of a voltage sensor for detecting a power supply voltage; a noise canceller connected to an output terminal of the first analog-to-digital converter; a phase corrector connected to an output terminal of the second analog-to-digital converter; a first mixer connected to an output terminal of the noise canceller and an output terminal of the phase corrector; a low-pass filter connected to an output terminal of the first mixer; a second mixer connected to an output terminal of the low-pass filter; a gain corrector for providing a gain correction value to the second mixer; and a controller connected to the phase corrector and the gain corrector to provide a control signal.

At this time, the metering chip may further include a DC blocker between the output terminal of the second analog-to-digital converter and the phase corrector.

Further, the phase corrector may include an all-pass filter having one end connected to an output terminal of the DC blocker and the other end connected to the first mixer; and a phase correction signal generator connected to the controller to generate a phase correction signal according to the control signal and provide the phase correction signal to the all-pass filter.

Further, the metering chip may further include a communication port connected to an output terminal of the second mixer.

Further, the noise canceller may include a digital filter connected to the output terminal of the first analog-to-digital converter; and an adder connected to the output terminal of the first analog-to-digital converter and an output terminal of the digital filter.

Further, the digital filter may be a filter which passes only a signal deviated from a center frequency domain of a signal output from the first analog-to-digital converter, and the adder may subtract the signal passing through the digital filter from the signal output from the first analog-to-digital converter to output the subtracted signal.

Further, a transfer function H(z) of the digital filter is

$$H ( z ) = \frac{1 - 2 cos {ω}_{0} {z}^{- 1} + {z}^{- 2}}{1 - 2 r cos {ω}_{0} {z}^{- 1} + {r}^{2} {z}^{- 2}} .$$

At this time, r is

$$r = 1 - \frac{Δ f}{{f}_{s}} π$$

as a radius from a center point to a pole position on a unit circle of a z plane. At this time, fₒ is a center frequency, Δf is a band frequency, fₛ is a sampling frequency, and ωₒ is

$${ω}_{0} = \frac{2 π {f}_{0}}{{f}_{s}}$$

as an angular frequency of a pole on the unit circle of the z plane, and the adder may subtract the signal passing through the digital filter from the signal output from the first analog-to-digital filter to output the subtracted signal.

Further, the first analog-to-digital converter may have a resolution of less than 12 bits.

Further, the first analog-to-digital converter may be a sigma-delta analog-to-digital converter with a resolution of less than 12 bits.

Further, the first analog-to-digital converter may be a flash analog-to-digital converter with a resolution of less than 12 bits.

In accordance with still another aspect of the present invention to achieve the object, there is provided a method of metering including the steps of: detecting a power supply current as an analog current signal; converting the detected analog current signal into a digital current signal; outputting the noise-removed digital current signal by removing noise from the digital current signal; and outputting a first power signal by mixing the noise-removed digital current signal with a digital voltage signal according to a power supply voltage.

At this time, the step of outputting the noise-removed digital current signal by removing noise from the digital current signal may filter the digital current signal by a digital filter which passes the signal deviated from a center frequency domain of the digital current signal to output a difference from the digital current signal.

Further, a transfer function H(z) of the digital filter is

$$H ( z ) = \frac{1 - 2 cos {ω}_{0} {z}^{- 1} + {z}^{- 2}}{1 - 2 r cos {ω}_{0} {z}^{- 1} + {r}^{2} {z}^{- 2}} .$$

At this time, r is

$$r = 1 - \frac{Δ f}{{f}_{s}} π$$

as a radius from a center point to a pole position on a unit circle of a z plane. At this time, fₒ is a center frequency, Δf is a band frequency, fₛ is a sampling frequency, and ωₒ is

$${ω}_{0} = \frac{2 π {f}_{0}}{{f}_{s}}$$

as an angular frequency of a pole on the unit circle of the z plane.

Further, the method of metering may further include the steps of: filtering the first power signal by a low-pass filter; and outputting a second power signal by mixing the filtered first power signal with a gain correction signal.

Further, the digital voltage signal according to the power supply voltage may be mixed with the noise-removed digital current signal through the steps of: detecting the power supply voltage as an analog voltage signal; converting the detected analog voltage signal into a digital voltage signal; removing a DC offset from the digital voltage signal; and correcting a phase so that the phase of the DC offset-removed digital voltage signal corresponds to the noise-removed digital current signal.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view schematically showing a metering chip in accordance with an embodiment of the present invention;

FIG. 2 is a view schematically showing a noise canceller of the metering chip in accordance with an embodiment of the present invention;

FIG. 3 is a view schematically showing a frequency response of a digital filter included in the noise canceller of the metering chip in accordance with an embodiment of the present invention;

FIG. 4 is a view schematically showing a low SNR signal generated by mixing noise in a current signal;

FIG. 5 is a view for comparing a noise-free digital current signal with a signal output from the noise canceller of the metering chip in accordance with an embodiment of the present invention;

FIG. 6a is a view schematically showing an error rate compared to a current in a metering chip in accordance with the prior art and the metering chip in accordance with an embodiment of the present invention;

FIG. 6b is an enlarged view of some sections of FIG. 6a;

FIG. 7a is a view schematically showing an error rate compared to a current in the metering chip in accordance with the prior art and the metering chip in accordance with an embodiment of the present invention; and

FIG. 7b is an enlarged view of some sections of FIG. 7a.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art. The same reference numerals refer to the same elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help understanding of embodiments of the present invention. The same reference numerals in different figures denote the same elements and the similar reference numerals do not necessarily all refer to the similar elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Hereinafter, configurations and effects of the present invention will be described in detail with reference to the accompanying drawings.

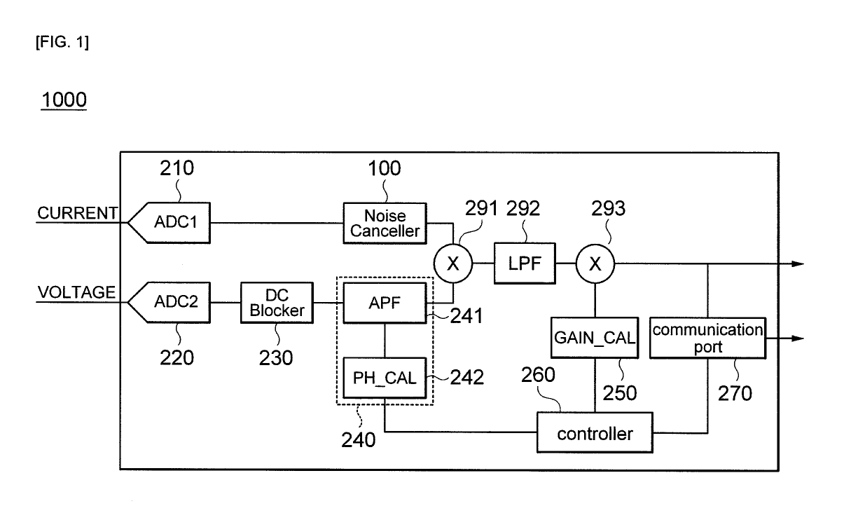

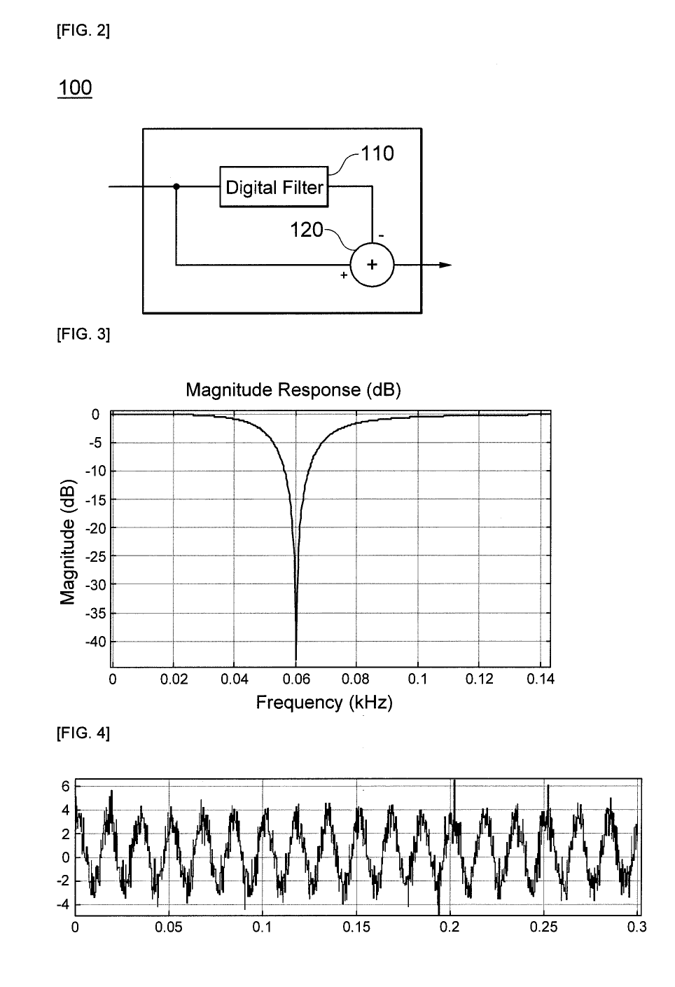

FIG. 1 is a view schematically showing a metering chip 1000 in accordance with an embodiment of the present invention, and FIG. 2 is a view schematically showing a noise canceller 100 of the metering chip 1000 in accordance with an embodiment of the present invention.

Referring to FIGS. 1 and 2, the metering chip 1000 in accordance with an embodiment of the present invention may include a first analog-to-digital converter 210, a second analog-to-digital converter 220, a noise canceller 100, a DC blocker 230, a phase corrector 240, a first mixer 291, a low-pass filter 292, a second mixer 293, a gain corrector 250, a controller 260, and a communication port 270.

The first analog-to-digital converter 210 is connected to an output terminal of a current sensor for detecting a power supply current. At this time, the current sensor outputs an analog current signal by detecting the power supply current, and the first analog-to-digital converter 210 converts the received analog current signal into a digital current signal to output the digital current signal.

The noise canceller 100 is connected to an output terminal of the first analog-to-digital converter 210.

The noise canceller 100 removes noise in the digital current signal output from the first analog-to-digital converter 210 to improve a signal-to-noise ratio (SNR).

Referring to FIG. 2, the noise canceller 100 provided in the metering chip 1000 in accordance with an embodiment of the present invention may include a digital filter 110 and an adder 120.

At this time, one end of the digital filter 110 is connected to the first analog-to-digital converter 210, and the other end thereof is connected to the adder 120.

Further, the adder 120 is connected to the output terminal of the first analog-to-digital converter 210 and the digital filter 110 and adds the digital current signal and the digital current signal passing through the digital filter 110 to output the added signal.

At this time, the digital filter 110 may be a filter which passes only a signal deviated from a center frequency domain of the signal output from the first analog-to-digital converter 210 and remove the noise of the digital current signal by subtracting the signal passing through the digital filter 110 from the output signal of the first analog-to-digital converter 210 input into the adder 120.

FIG. 3 is a view schematically showing a frequency response of the digital filter 110 included in the noise canceller 100 of the metering chip 1000 in accordance with an embodiment of the present invention.

Referring to FIG. 3, it will be appreciated that the digital filter 110 included in the noise canceller 100 of the metering chip 1000 in accordance with an embodiment of the present invention performs an operation of blocking the signals near a center frequency of 60 Hz and passing the remaining signals. However, at this time, although FIG. 3 shows that the center frequency is 60 Hz which is a commercial power, it is not limited thereto.

Meanwhile, a transfer function H(z) of the digital filter 110 may be defined as

$$H ( z ) = \frac{1 - 2 cos {ω}_{0} {z}^{- 1} + {z}^{- 2}}{1 - 2 r cos {ω}_{0} {z}^{- 1} + {r}^{2} {z}^{- 2}}$$

to implement the above-described characteristics.

At this time, r is a radius from a center point to a pole position on a unit circle of a Z plane and may be defined as

$$r = 1 - \frac{Δ f}{{f}_{s}} π .$$

Here, fₒ is a center frequency, Δf is a band frequency, fₛ is a sampling frequency, and ωo is an angular frequency of a pole on the unit circle of the z plane and may be defined as

$${ω}_{0} = \frac{2 π {f}_{0}}{{f}_{s}} .$$

For example, when the center frequency fₒ: 60 Hz,

the band frequency Δf: 1 Hz, and

the sampling frequency fₛ: 1e6/256 Hz,

if calculating the transfer function,

r=1−1/(Fₛ)*pi=0.9992, and

ωₒ=(2*pi*60)/(Fₛ)=0.0965

If applying r and ωₒ to the above-described transfer function formula,

$$\begin{matrix}H ( z ) = \frac{1 - 2 cos {ω}_{0} {z}^{- 1} + {z}^{- 2}}{1 - 2 r cos {ω}_{0} {z}^{- 1} + {r}^{2} {z}^{- 2}} \\ = 1 - 1.9907 {z}^{- 1} + {z}^{- 2} / 1 - 1.9891 {z}^{- 1} + 0.9984 {z}^{- 2}\end{matrix}$$

Like this, the digital current signal whose noise is removed by the noise canceller 100 is provided to the first mixer 291.

The first mixer 291 may output a signal representing a power value by mixing the noise-removed digital current signal with a digital voltage signal according to a power supply voltage.

At this time, the low-pass filter 292 may be connected to an output terminal of the first mixer 291 to remove a ripple of the power value.

Further, the second mixer 293 may be further provided to mix a gain value for compensating an error of power. At this time, the gain value may be provided by the gain corrector 250 which generates the gain value according to a control signal of the controller 260.

Meanwhile, generally, the power supply voltage can be maintained as a constant value within a predetermined range. Thus, the digital voltage signal for calculating the amount of power may be replaced with an arbitrary digital signal waveform.

However, in order to perform accurate measurement of the amount of power by reflecting even changes in the power supply voltage, separate elements may be required to detect and process the power supply voltage.

Therefore, the elements for processing the power supply voltage will be specifically described below with reference to FIG. 1.

The power supply voltage may be detected as an analog voltage signal by a separate voltage sensor.

The second analog-to-digital converter 220 may be connected to an output terminal of the voltage sensor and convert the analog voltage signal into the digital voltage signal to output the digital voltage signal.

Meanwhile, there may be a phase difference between the power supply voltage and the power supply current, and the phase corrector 240 may be provided to correct the phase difference.

The phase corrector 240 may include an all-pass filter 241.

Further, the phase corrector 240 may include a phase correction signal generator 242 which generates a phase correction signal according to the control signal of the controller 260 to provide the phase correction signal to the all-pass filter 241.

Meanwhile, since a DC offset may be included in the digital voltage signal output from the second analog-to-digital converter 220, the DC blocker 230 may be further provided between the second analog-to-digital converter 220 and the phase corrector 240 to remove the DC offset.

The digital voltage signal passing through the second analog-to-digital converter 220, the DC blocker 230, and the phase corrector 240 is input into the first mixer 291 to be multiplied with the noise-removed digital current signal, thus calculating power.

Meanwhile, the calculated power may be output to the outside through the communication port 270 such as SPI. Accordingly, the calculated power is displayed to allow users to check the amount of power or provided to CPUs of intelligent appliances with the metering chip 1000 to be utilized for implementation of a DR interlocking function.

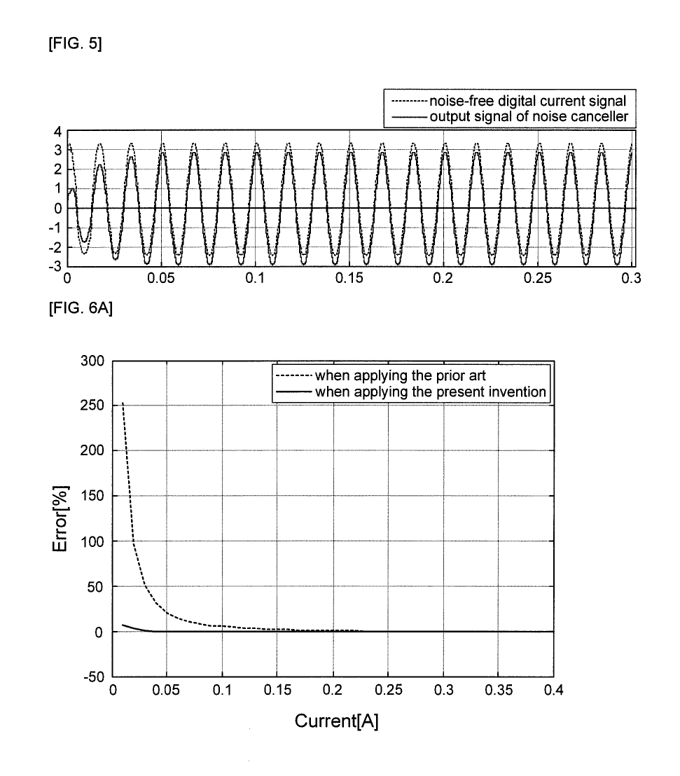

FIG. 4 is a view schematically showing a low SNR signal generated by mixing noise in a current signal.

In order to perform modeling for a current signal in which a lot of noise is mixed, FIG. 4 shows a signal generated by adding noise to a sine wave signal including a DC offset.

FIG. 5 is a view for comparing a noise-free digital current signal with a signal output from the noise canceller 100 of the metering chip 1000 in accordance with an embodiment of the present invention.

Referring to FIG. 5, it is possible to check that the noise canceller 100 of the metering chip 1000 in accordance with an embodiment of the present invention removes most of the noise component to output a signal close to the noise-free digital current signal.

FIG. 6a is a view schematically showing an error rate compared to a current in a metering chip 1000 in accordance with the prior art and the metering chip 1000 in accordance with an embodiment of the present invention, and FIG. 6b is a view showing some sections of FIG. 6A enlarged in the Y-axis direction.

Generally, a dynamic range is mainly used as an indicator of performance of the analog-to-digital converter mounted to the metering chip 1000.

For example, when a current varies in the range of 1 A to 20 A, the dynamic range of the analog-to-digital converter, which secures an error of the amount of power of less than 1%, is 20/1=20:1.

Further, when a current varies in the range of 0.1 A to 20 A, the dynamic range of the analog-to-digital converter, which secures the error of the amount of power of less than 1%, is 20/0.5=40:1.

At this time, the analog-to-digital converter has excellent performance when the dynamic range is 40:1 compared to the case when the dynamic range is 20:1.

FIGS. 6a and 6b show the result of comparison of errors by setting a maximum current to 20 A and measuring a current effective value in a current section of 0.01 to 0.4 A.

Here, application of the prior art means the case in which only an analog-to-digital converter with a resolution of 24 bits is used, and application of the present invention means the case in which the first analog-to-digital converter 210 is implemented as an analog-to-digital converter with a resolution of 12 bits in the metering chip 1000 in accordance with an embodiment of the present invention.

Referring to 6b, it will be appreciated that the dynamic range at the time of applying the present invention is 20/0.02=1000:1 and the dynamic range at the time of applying the prior art is 20/0.25=80:1 when a section in which the error of the amount of power of less than 1% is secured is set as the dynamic range.

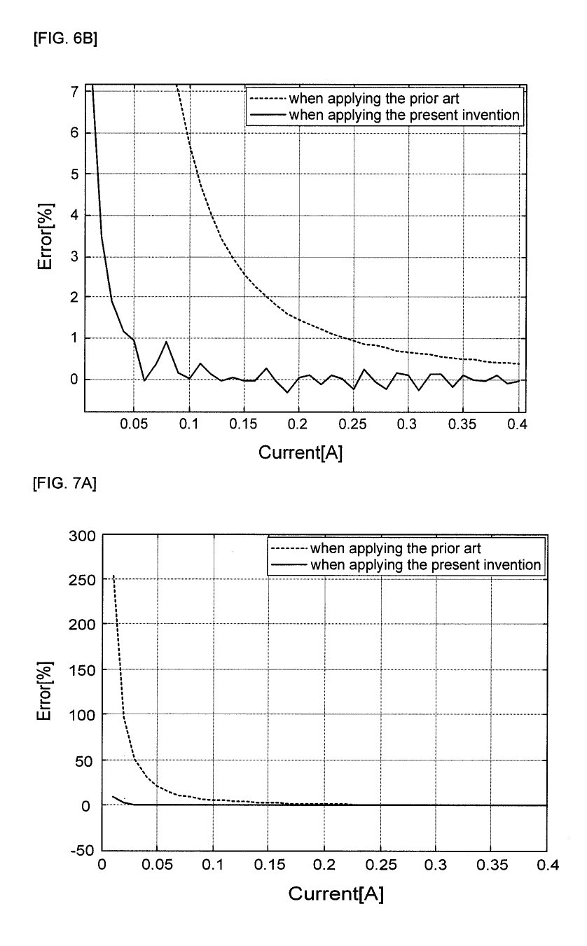

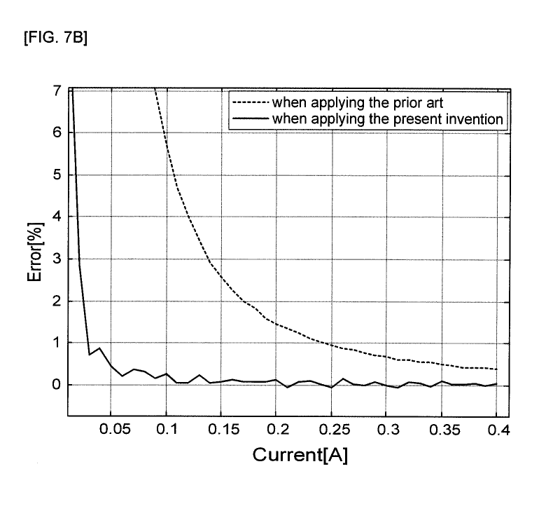

FIG. 7a is a view schematically showing an error rate compared to a current in the metering chip 1000 in accordance with the prior art and the metering chip 1000 in accordance with an embodiment of the present invention, and FIG. 7b is a view showing some sections of FIG. 7a enlarged in the Y-axis direction.

FIGS. 7a and 7b show the result of comparison of errors by setting a maximum current to 40 A and measuring a current effective value in a current section of 0.01 to 0.4 A.

Referring to FIG. 7b, it will be appreciated that the dynamic range at the time of applying the present invention is 40/0.05=800:1 and the dynamic range at the time of applying the prior art is 40/0.25=160:1 when a section in which the error of the amount of power of less than 1% is secured is set as the dynamic range.

Generally, according to a rule of thumb for calculating a resolution required for an analog-to-digital converter, when securing an error of the amount of power of less than 1% in the dynamic range of 320:1, a resolution of greater than 14.9 bits is required as in the following formula.

1%/320=0.01/320=0.00003125

log(0.00003125)/log(2)=14.9 bit

The above formula is applied to the above-described example with reference to FIGS. 6a and 6b.

According to the conventional general rule of thumb, in order to satisfy error performance of 1% in the dynamic range of 1000:1, an analog-to-digital converter with a resolution of greater than 16.6 bits is required as in the following formula.

log(0.01/1000)log(2)=16.6 bit

That is, it is possible to satisfy the error performance of 1% in the dynamic range of 1000:1 when the resolution is greater than at least 17 bits.

However, the metering chip 1000 in accordance with an embodiment of the present invention can satisfy the error performance of 1% in the dynamic range of 1000:1 even using the first analog-to-digital converter 210 with a resolution of 12 bits.

Similarly, the above formula is applied to the above-described example with reference to FIGS. 7a and 7b.

According to the conventional general rule of thumb, in order to satisfy the error performance of 1% in the dynamic range of 320:1, an analog-to-digital converter with a resolution of greater than 14.79 bits is required as in the following formula.

log(0.01/320)log(2)=14.79 bit

That is, it is possible to satisfy the error performance of 1% in the dynamic range of 320:1 when the resolution is greater than at least 15 bits.

However, the metering chip 1000 in accordance with an embodiment of the present invention can satisfy the error performance of 1% in the dynamic range of 320:1 even using the first analog-to-digital converter 210 with a resolution of 12 bits.

For the metering chip 1000 that can be applied to intelligent appliances, miniaturization and minimization of power consumption as well as reduction of manufacturing costs are required rather than performance.

In case of the typical metering chips 1000 for charging, accuracy from class 2, class 1 to class 0.5 or less is an important determining factor, but in case of the metering chips for home appliances, class 2 (±2%) is enough.

Therefore, since the typical metering chips 1000 for charging on the market are manufactured while giving a priority to accuracy, they are not suitable for being applied to home appliances as they are.

Meanwhile, in calculation of manufacturing costs of the metering chip 1000 which is a semiconductor, if considering material costs only, the manufacturing costs are greatly influenced by minimization of an area of a wafer for implementing the metering chip 1000.

Further, when reducing a size of the metering chip 1000 in a technically acceptable range, it is possible to reduce power consumption and manufacturing costs at the same time.

Generally, an analog block occupies more physical area than a digital block in semiconductor processes.

In case of the metering chip 1000, the analog-to-digital converter corresponds to the analog block. In order to increase the resolution of the analog-to-digital converter, since the number of bits to be processed is increased as well as an order of a modulator, power consumption is increased according to an increase in logic size.

Therefore, it is possible to remarkably reduce the size of the entire metering chip 1000 by reducing the resolution of the analog-to-digital converter, thus reducing power consumption as well.

However, when reducing the resolution of the analog-to-digital converter, a capability of detecting a low current is rapidly deteriorated. Thus, the prior art couldn't implement the metering chip 1000 using a low resolution analog-to-digital converter.

However, the metering chip 1000 in accordance with an embodiment of the present invention described above can sufficiently compensate a performance of detecting a low current by providing the noise canceller 100 in the output terminal of the first analog-to-digital converter 210. This will be sufficiently appreciated from the foregoing description referring to FIGS. 6a to 7a.

Accordingly, the metering chip 1000 in accordance with an embodiment of the present invention can be implemented by including an analog-to-digital converter with a resolution of less than 12 bits to minimize the size thereof and reduce power consumption at the same time. At this time, a sigma-delta analog-to-digital converter or a flash analog-to-digital converter may be applied as the analog-to-digital converter.

Meanwhile, a method of metering in accordance with an embodiment of the present invention may remove noise from a digital current signal and mix the noise-removed digital current signal with a digital voltage signal.

At this time, the process of removing noise may be implemented in such a way that filters the digital current signal through a digital filter 110, which passes only the signal deviated from a center frequency domain of the digital current signal, and outputs a difference from the digital current signal.

The present invention configured as above can provide a metering chip that can effectively detect a low current even though a resolution of an analog-to-digital converter is low.

Accordingly, since the metering chip can reduce its power consumption and be implemented with a much smaller size than before, it is advantageous to implementation of a DR interlocking function by being applied to intelligent home appliances and so on.

Further, the present invention can provide a method of metering that can effectively detect a low current even though a resolution of an analog-to-digital converter is low.

What is claimed is:

1. A metering chip for calculating the amount of power by detecting a power supply current and a power supply voltage, comprising:
a first analog-to-digital converter connected to an output terminal of a current sensor for detecting the power supply current; and
a noise canceller connected to an output terminal of the first analog-to-digital converter.

2. The metering chip according to claim 1, wherein the noise canceller comprises:
a digital filter connected to the output terminal of the first analog-to-digital converter; and
an adder connected to the output terminal of the first analog-to-digital converter and an output terminal of the digital filter.

3. The metering chip according to claim 2, wherein the digital filter is a filter which passes only a signal deviated from a center frequency domain of a signal output from the first analog-to-digital converter, and
the adder subtracts the signal passing through the digital filter from the signal output from the first analog-to-digital converter to output the subtracted signal.

4. The metering chip according to claim 2, wherein a transfer function H(z) of the digital filter is
$$H ( z ) = \frac{1 - 2 cos {ω}_{0} {z}^{- 1} + {z}^{- 2}}{1 - 2 r cos {ω}_{0} {z}^{- 1} + {r}^{2} {z}^{- 2}} ,$$
wherein
r is
$$r = 1 - \frac{Δ f}{{f}_{s}} π$$
as a radius from a center point to a pole position on a unit circle of a z plane, wherein
fₒ is a center frequency, Δf is a band frequency, fₛ is a sampling frequency, and ωₒ is
$${ω}_{0} = \frac{2 π {f}_{0}}{{f}_{s}}$$
as an angular frequency of a pole on the unit circle of the z plane, and
the adder subtracts a signal passing through the digital filter from a signal output from the first analog-to-digital filter to output the subtracted signal.

5. A metering chip comprising:
a first analog-to-digital converter connected to an output terminal of a current sensor for detecting a power supply current;
a second analog-to-digital converter connected to an output terminal of a voltage sensor for detecting a power supply voltage;
a noise canceller connected to an output terminal of the first analog-to-digital converter;
a phase corrector connected to an output terminal of the second analog-to-digital converter;
a first mixer connected to an output terminal of the noise canceller and an output terminal of the phase corrector;
a low-pass filter connected to an output terminal of the first mixer;
a second mixer connected to an output terminal of the low-pass filter;
a gain corrector for providing a gain correction value to the second mixer; and
a controller connected to the phase corrector and the gain corrector to provide a control signal.

6. The metering chip according to claim 5, further comprising:
a DC blocker between the output terminal of the second analog-to-digital converter and the phase corrector.

7. The metering chip according to claim 6, wherein the phase corrector comprises:
an all-pass filter having one end connected to an output terminal of the DC blocker and the other end connected to the first mixer; and
a phase correction signal generator connected to the controller to generate a phase correction signal according to the control signal and provide the phase correction signal to the all-pass filter.

8. The metering chip according to claim 5, further comprising:
a communication port connected to an output terminal of the second mixer.

9. The metering chip according to claim 5, wherein the noise canceller comprises:
a digital filter connected to the output terminal of the first analog-to-digital converter; and
an adder connected to the output terminal of the first analog-to-digital converter and an output terminal of the digital filter.

10. The metering chip according to claim 9, wherein the digital filter is a filter which passes only a signal deviated from a center frequency domain of a signal output from the first analog-to-digital converter, and
the adder subtracts the signal passing through the digital filter from the signal output from the first analog-to-digital converter to output the subtracted signal.

11. The metering chip according to claim 9, wherein a transfer function H(z) of the digital filter is
$$H ( z ) = \frac{1 - 2 cos {ω}_{0} {z}^{- 1} + {z}^{- 2}}{1 - 2 r cos {ω}_{0} {z}^{- 1} + {r}^{2} {z}^{- 2}} ,$$
wherein
r is
$$r = 1 - \frac{Δ f}{{f}_{s}} π$$
as a radius from a center point to a pole position on a unit circle of a z plane, wherein
fₒ is a center frequency, Δf is a band frequency, fₛ is a sampling frequency, and ωₒ is
$${ω}_{0} = \frac{2 π {f}_{0}}{{f}_{s}}$$
as an angular frequency of a pole on the unit circle of the z plane, and the adder subtracts a signal passing through the digital filter from a signal output from the first analog-to-digital filter to output the subtracted signal.

12. The metering chip according to claim 5, wherein the first analog-to-digital converter has a resolution of less than 12 bits.

13. The metering chip according to claim 5, wherein the first analog-to-digital converter is a sigma-delta analog-to-digital converter with a resolution of less than 12 bits.

14. The metering chip according to claim 5, wherein the first analog-to-digital converter is a flash analog-to-digital converter with a resolution of less than 12 bits.

15. A method of metering, comprising:
detecting a power supply current as an analog current signal;
converting the detected analog current signal into a digital current signal;
outputting the noise-removed digital current signal by removing noise from the digital current signal; and
outputting a first power signal by mixing the noise-removed digital current signal with a digital voltage signal according to a power supply voltage.

16. The method of metering according to claim 15, wherein outputting the noise-removed digital current signal by removing noise from the digital current signal filters the digital current signal by a digital filter which passes the signal deviated from a center frequency domain of the digital current signal to output a difference from the digital current signal.

17. The method of metering according to claim 16, wherein a transfer function H(z) of the digital filter is
$$H ( z ) = \frac{1 - 2 cos {ω}_{0} {z}^{- 1} + {z}^{- 2}}{1 - 2 r cos {ω}_{0} {z}^{- 1} + {r}^{2} {z}^{- 2}} ,$$
wherein ‘r is
$$r = 1 - \frac{Δ f}{{f}_{s}} π$$
as a radius from a center point to a pole position on a unit circle of a z plane, wherein
fₒ is a center frequency, Δf is a band frequency, fₛ is a sampling frequency, and ωₒ is
$${ω}_{0} = \frac{2 π {f}_{0}}{{f}_{s}}$$
as an angular frequency of a pole on the unit circle of the z plane.

18. The method of metering according to claim 15, further comprising:
filtering the first power signal by a low-pass filter; and
outputting a second power signal by mixing the filtered first power signal with a gain correction signal.

19. The method of metering according to claim 18, wherein the digital voltage signal according to the power supply voltage is mixed with the noise-removed digital current signal through:
detecting the power supply voltage as an analog voltage signal;
converting the detected analog voltage signal into a digital voltage signal;
removing a DC offset from the digital voltage signal; and
correcting a phase so that the phase of the DC offset-removed digital voltage signal corresponds to the noise-removed digital current signal.
